(19) United States
(12) Patent Application Publication
(10) Pub. No.: US 2026/0309763 A1
(43) Pub. Date: Oct. 8, 2026

(54) APPARATUS AND METHOD FOR FAULT POSITIONING IN ELECTRICAL GRIDS

(71) Applicant: Safegrid Oy, Espoo (FI)

(72) Inventor: Tapio Mäntysalo, Hevonpää (FI)

(73) Assignee: Safegrid Oy, Espoo (FI)

(21) Appl. No.: 19/485,033

(22) PCT Filed: Jun. 13, 2024
(86) PCT No.: PCT/FI2024/050307

§ 371 Date: Nov. 17, 2025

(30) Foreign Application Priority Data
Jun. 26, 2023 (FI) 20235740

(51) Int. Cl. G01R 31/08

(52) U.S. Cl. CPC G01R 31/085; G01R 31/088

(57) ABSTRACT

A system for detection of fault location in electric grid (EG), the system including traveling wave fault recording units (TWFRU) configured to be installed at various locations in EG, to detect and record arrival times of traveling waves, and processing arrangement communicably coupled with TWFRU, wherein processing arrangement is configured to receive, from TWFRU, information about recorded arrival times of detected traveling waves, identify primary fault location candidate (PFLC) in faulty feeder line (FFL)-(204A, in EG based on received information, receive, from one or more sensor units, one or more measured current values, wherein given measured current value corresponds to fault current value in FFL when given measured current value represents phase-to-phase, phase-to-neutral, or phase-to-ground fault, identify secondary fault location candidates (SFLC) in FFL, based on processing of the received fault current value, and determine fault location based on comparison of identified PFLC and SFLC in faulty feeder line.

### TECHNICAL FIELD

The present disclosure relates to a system for detection of a fault location in an electric grid. Moreover, the present disclosure relates to a method for detection of a fault location in an electric grid.

### BACKGROUND

Generally, an electric grid comprises power lines, power poles, transformers, switching circuits, protection circuits, and so forth. Typically, such an electric grid may be prone to occurrence of faults due to lighting, storms, falling of trees on power lines, failure of apparatus, and the like. As an example, the fault may cause problems such as over current, under voltage, unbalancing of three phases, high voltage surges, and the like. These faults may cause deviations in voltage values and current values from their nominal ranges in the electric grid. Examples of the faults include transient faults, ground faults, arcing faults, short circuit faults, open circuit faults, overload faults, broken conductors, lost phases, and partial discharges. Most of the faults in the electric grid are transient in nature. For example, a transient fault may occur due to for example, trees falling onto the overhead lines, incautious excavation performed nearby underground cables, a bird or an animal coming in contact with the overhead lines, a lightning strike, a clash of conductors due to an external force (such as high wind speed), cracks or impurities in insulation material, and the like. The management of an electric grid comprises accurately detecting the said faults and errors in the electric grid and/or the electrical components operating therein. However, such an operation is highly complex and cumbersome.

The present solutions for detecting the fault in the electric grid involve recording different arrival times of traveling waves that are generated by the occurrence of said fault in the electric grid and detect the location of the fault within a faulty feeder section of the electric grid. However, such solutions fail to provide a way to detect the location of the fault within a plurality of branches in the faulty feeder section of the electric grid. Moreover, some other present solutions for detection of the fault in the electric grid involve using a fault current value of a fault current that is generated in the electric grid due to the occurrence of the fault, to determine the location of the fault. However, using the fault current value to determine the location of the fault provides multiple possible locations for the fault, where detecting the accurate location of the fault from amongst the multiple possible locations of the fault is highly cumbersome and time consuming.

Therefore, in light of the foregoing discussion, there exists a need to overcome the aforementioned drawbacks.

### SUMMARY

The aim of the present disclosure is to provide a system and a method to accurately detect a fault location in an electric grid. The aim of the present disclosure is achieved by a system and a method for detection of a fault location in an electric grid as defined in the appended independent claims to which reference is made to. Advantageous features are set out in the appended dependent claims.

Throughout the description and claims of this specification, the words “comprise”, “include”, “have”, and “contain” and variations of these words, for example “comprising” and “comprises”, mean “including but not limited to”, and do not exclude other components, items, integers or steps not explicitly disclosed also to be present. Moreover, the singular encompasses the plural unless the context otherwise requires. In particular, where the indefinite article is used, the specification is to be understood as contemplating plurality as well as singularity, unless the context requires otherwise.

### BRIEF DESCRIPTION OF THE DRAWINGS

FIG. 1 is an illustration of a block diagram of a system for detection of a fault location in an electric grid, in accordance with an embodiment of the present disclosure;

FIG. 2 is a schematic illustration of an electric grid depicting a detection of a fault location, in accordance with an embodiment of the present disclosure;

FIG. 3 is a schematic illustration of an electric grid depicting a detection of a fault location, in accordance with an embodiment of the present disclosure;

FIG. 4 is an exemplary depiction of an electric grid, in accordance with one or more embodiments of the present disclosure;

FIG. 5 is an exemplary depiction of an electric grid, in accordance with one or more embodiments of the present disclosure; and

FIGS. 6 and 6 (cont'd) are a flowchart depicting steps of a method for detection of a fault location in an electric grid, in accordance with an embodiment of the present disclosure.

### DETAILED DESCRIPTION OF EMBODIMENTS

The following detailed description illustrates embodiments of the present disclosure and ways in which they can be implemented. Although some modes of carrying out the present disclosure have been disclosed, those skilled in the art would recognize that other embodiments for carrying out or practising the present disclosure are also possible.

In a first aspect, the present disclosure provides a system for detection a fault location in an electric grid, the system comprising:
a plurality of traveling wave fault recording units configured to be installed at locations in the electric grid, to detect and record arrival times traveling waves generated by occurrence of a fault or an event in a given feeder line, and
a processing arrangement communicably coupled with the plurality of traveling wave fault recording units, wherein the processing arrangement configured to:
   receive, from the plurality of traveling wave fault recording units, information about the recorded arrival times of the detected traveling waves and the location coordinates thereof in the electric grid,
   identify a primary fault location candidate in a faulty feeder line in the electric grid based on the received information,
   receive, from one or more sensor units, installed in the faulty feeder line, one or more measured current values during the occurrence of the fault, wherein a given measured current value corresponds to a fault current value in the faulty feeder line when the given measured current value represents a phase-to-phase, phase-to-neutral, or phase-to-ground fault,
   identify one or many secondary fault location candidates in the faulty feeder line, based on a processing of the received fault current value for each corresponding branch from amongst a plurality of branches of the faulty feeder line, and
   determine the fault location based on a comparison of the identified primary fault location candidate and the one or many secondary fault location candidates in the faulty feeder line.

The present disclosure provides the aforementioned system for detection a fault location in an electric grid. The system facilitates to significantly improve an accuracy of detection of the fault location in the electric grid by comparing the primary fault location candidate with the one or many secondary fault location candidates. Moreover, the system effectively and accurately detects the fault location from a plurality of possible fault locations. Furthermore, the system is cost-effective, less time consuming and easy to implement.

In a second aspect, the present disclosure provides a method for detection of a fault location in an electric grid, the method comprising:
detecting and recording, via a plurality of traveling wave fault recording units, arrival times of traveling waves generated by occurrence of a fault or an event in a given feeder line;
receiving, from the plurality of traveling wave fault recording units, via a processing arrangement, information about the recorded arrival times of the detected traveling waves;
identifying, via the processing arrangement, a primary fault location candidate in a faulty feeder line in the electric grid based on the received information;
receiving, from one or more sensor units installed in the faulty feeder line, via the processing arrangement, one or more measured current values during the occurrence of the fault, wherein a given measured current value corresponds to a fault current value in the faulty feeder line when the given measured current value represents a phase-to-phase, phase-to-neutral, or phase-to-ground fault;
identifying, via the processing arrangement, one or many secondary fault location candidates in the faulty feeder line, based on a processing of the received fault current value for each corresponding branch from amongst a plurality of branches of the faulty feeder line; and
determining, via the processing arrangement, the fault location based on comparing the identified primary fault location candidate and the one or many secondary fault location candidates in the faulty feeder line.

The present disclosure provides the aforementioned method for detection of a fault location in an electric grid. The system facilitates to significantly improve an accuracy of detection of the fault location in the electric grid by comparing the primary fault location candidate with the one or many secondary fault location candidates, by combining the fault detection using the traveling wave fault recording technique and the fault current in the faulty feeder line.

Throughout the present disclosure, the term “electric grid” refers to a complex network of interconnected power generation sources, transmission lines (transmission grid), distribution systems (distribution grid) and end consumers which enables a distribution and transmission of electrical power. Notably, the electric grid is essential for facilitating an effective delivery of electricity from the power generation sources to the end consumers. It will be appreciated that the electric grid is of different configurations based on different levels of complexity based on factors such as an area of operation, a number of consumers, types of the power generation sources, geographical location, and the like.

The terms “transmission grid” and “distribution grid” may refer to different components of the overall electrical power system that may be parts of the electric grid. The transmission grid is responsible for the bulk transfer of electricity over long distances from power plants to distribution substations. The transmission grid comprises high-voltage power lines (often operating at hundreds of kilovolts or megavolts), transformers, and other associated equipment. Notably, a primary function of the transmission grid is to transmit large amounts of electricity efficiently and reliably over a wide area. The transmission grid is operated by grid operators or system operators who manage the flow of electricity and maintain the stability of the system. The distribution grid, also known as the local distribution network, the medium voltage grid, or simply the “grid” is the portion of the power system that delivers electricity from distribution substations to individual consumers. The distribution grid operates at lower voltage levels, typically in the range of a few kilovolts (kV) to tens of kilovolts. The distribution grid includes medium-voltage power lines, transformers, switchgear, and other components necessary for the safe and efficient distribution of electricity to homes, businesses, and industries. The distribution grid is managed by local utilities or distribution system operators (DSOs) who are responsible for maintaining the reliability of electricity supply in their respective areas.

For example, in urban areas, the high-voltage power line of the electric grid typically branches into several medium-voltage lines, typically at range between 1 and 35 kilovolts (kV), and finally into low-voltage lines, for example 400 volts (V), in residential areas. However, there can be feeder lines up to 60 kV. In sparsely populated areas, the lines are usually overhead lines, and in cities, the common solution is typically an underground cable.

In addition to the above transmission grid and distribution grid, there can be a generation grid that may be a part of the electric grid. The term “generation grid” may refer to the collective infrastructure and interconnected power plants that generate electricity. It encompasses a variety of generation sources, including thermal power plants, hydroelectric plants, wind farms, solar power plants, and others. These generation facilities are often connected to the transmission grid, which allows the produced electricity to be transmitted to distribution networks and eventually reach consumers.

Throughout the present disclosure, the term “fault location” refers to a specific physical location in the electric grid where the fault has occurred in the electric grid. Notably, accurate detection of the fault location is required to enable a timely repairing of the fault. Throughout the present disclosure, the term “fault” refers to any type of defect or failure that arises in a certain part of the electric grid which hinders an operation of the electric grid. Examples of the faults include but are not limited to, transient faults, ground faults, arcing faults, short circuit faults, open circuit faults, overload faults, broken conductors, lost phases, and partial discharges.

The system comprises the plurality of traveling wave fault recording units configured to be installed at the locations in the electric grid, to detect and record the arrival times of the traveling waves generated by occurrence of the fault or the event in the given feeder line. Throughout the present disclosure, the term “feeder line” refers to a power line present in the electric grid which connects a distribution substation to an end consumer to supply electricity. Notably, the feeder line is a form of a distribution line or a transmission line. It will be appreciated that the electric grid comprises a plurality of feeder lines that are radial in nature, i.e., multiple feeder lines originate from a given distribution substation and extend in a branching pattern to connect with multiple end consumers. Notably, the plurality of feeder lines acts as distribution units in the electric grid that supplies electricity from various distribution substations to different end consumers (such as residential areas, commercial buildings, industrial facilities, and the like) present in the electric grid. Herein, the term “given feeder line” refers to a specific feeder line from amongst the plurality of feeder lines present in the electric grid.

Notably, when the fault occurs in the given feeder line, the traveling waves are generated in the faulty feeder line. Throughout the present disclosure, the term “traveling waves” refers to electromagnetic waves of high frequency that travel in the electric grid due to occurrence of the fault in the given feeder line. It will be appreciated that the travelling waves are generated by a sudden change in voltage or current that happens due to the occurrence of the fault in the given feeder line. Notably, the travelling waves travel in both directions from the fault location. It will also be appreciated that the traveling waves are used for detecting the faulty feeder line by analysis of time delays between the arrival time of the travelling waves at different measurement points (i.e., the plurality of the travelling wave fault recording units) along the electric grid.

The use of the plurality of traveling wave fault recording units installed at the locations in the electric grid enables for determining primary fault location candidate in the present system. These traveling wave fault recording units are strategically placed, often 0.5 km (kilometer) to 5 km apart in dense urban electric grids, or 3 km to even 20 km apart in rural areas, and even longer distances in transmission lines, to accurately capture the location and route of the traveling wave fault signals generated by the fault in the electric grid. The sensors are installed on the feeder line, at various locations which may be known. After installation the sensors are further configured to send their location to the server, or to the processing arrangement. The traveling wave fault recording units are designed to detect and record the arrival time of these traveling waves as they traverse through the electric grid. The high-frequency traveling wave signals exhibit unique characteristics that facilitate their detection by the plurality of the traveling wave fault recording units. In present examples, the plurality of traveling wave fault recording units may incorporate GPS time synchronization therein to accurately timestamp the detected traveling wave signals. This ensures precise time correlation between the signals received by different traveling wave fault recording units, which is essential for determining the primary fault location candidate as discussed later in the description.

Moreover, the system comprises the processing arrangement communicably coupled with the plurality of traveling wave fault recording units. Throughout the present disclosure, the term “processing arrangement” refers to a hardware, software, firmware, or a combination of these, suitable for controlling the operation of the system. Examples of the processing arrangement include, but are not limited to, a microprocessor, a microcontroller, a complex instruction set computing (CISC) microprocessor, a reduced instruction set (RISC) microprocessor, a very long instruction word (VLIW) microprocessor, or any other type of processing circuit. Furthermore, the processing arrangement may refer to one or more individual processors, processing devices and various elements associated with a processing device that may be shared by other processing devices. Additionally, one or more individual processors, processing devices and elements are arranged in various architectures for responding to and processing the instructions that drive the system. Optionally, the processing arrangement is communicably coupled with the plurality of traveling wave fault recording units via a wireless communication interface (for example, a Wi-Fi® module, a GSM module, and the like).

Optionally, the plurality of traveling wave fault recording units are configured to detect the traveling waves which traverse along one or more of: neutral wire(s), ground wire(s), cable shield(s) thus propagating over open switches or gaps in the feeder lines in the electric grid. It may be understood that when a fault occurs in the electric grid, it generates high-frequency traveling wave signals. These signals may “along” over open switches or gaps, not by physically passing over them, but by traveling along alternative pathways, such as neutral wires that are common to high-voltage, medium-voltage, and low-voltage lines and cables. Consequently, even in the presence of gaps or breaks in the electrical infrastructure, the traveling wave fault signals beneficially, continue to propagate throughout the electric grid. This unique characteristic of traveling wave signals allows them to bypass conventional network topology constraints and reach the traveling wave fault recording units. The traveling wave fault recording units are designed to capture and analyse the high-frequency signals, enabling them to distinguish the traveling wave fault signals from other types of signals or noise present in the electric grid.

In present examples, the plurality of traveling wave fault recording units may be equipped with advanced sensing technology to accurately detect these traveling waves as they traverse along the various conducting pathways. Suitable sensors may include voltage sensors or Rogowski coils, which may effectively capture high-frequency signals in the presence of low-frequency power signals. Further, the plurality of traveling wave fault recording units may be installed at strategic locations within the urban electric grid, ensuring they are in close proximity to the neutral or ground wires of the different voltage levels. The traveling wave fault recording units may be positioned such that they may capture the traveling wave fault signals even if they propagate over the open switches or gaps. Further, the traveling wave fault recording units may be equipped with filtering capabilities to isolate high-frequency traveling wave signals from other background signals or noise in the neutral or ground wires, such as by employing bandpass filters tuned to the frequency range of interest which may help in isolating the traveling wave signals.

In an embodiment, the travelling wave fault recording unit configured to be installed in the electric grid is a dual-ended traveling wave fault recording unit which detect and record two different arrival times of the generated traveling waves from the two corresponding ends. Subsequently, the system comprises only one travelling wave fault recording unit configured to be installed in the electric grid, thus, advantageously, reducing a required cost to implement the system.

The processing arrangement is configured to receive, from the plurality of traveling wave fault recording units, information about the recorded arrival times of the detected traveling waves and the location coordinates thereof in the electric grid. This may be achieved through wired or wireless communication methods, such as fibre-optic cables, radiofrequency communication, or cellular networks. Further, the processing arrangement may receive information about the location coordinates of the plurality of traveling wave fault recording units in the electric grid. The processing arrangement, then, processes data from the plurality of traveling wave fault recording units, which includes the recorded arrival time of the detected traveling waves as well as the location coordinates of these units within the electric grid.

Moreover, the processing arrangement is configured to identify the primary fault location candidate in the faulty feeder line in the electric grid based on the received information. Throughout the present disclosure, the term “primary fault location candidate” refers to a possible location in the faulty feeder line at which the fault has occurred in the faulty feeder line. Throughout the present disclosure, the term “faulty feeder line” refers to the given feeder line in the electric grid in which the fault has occurred. Notably, identifying the primary fault location candidate enables to identify the faulty feeder line in the electric grid, as the feeder line in which the primary fault location candidate is located is identified as the faulty feeder line. The processing arrangement integrates the recorded arrival time data from multiple traveling wave fault recording units while taking into account the location coordinates of these traveling wave fault recording units within the electric grid to triangulate the position of the primary fault location candidate within the electric grid. In some examples, the processing arrangement may also consider other factors, such as the physical topology of the electric grid or the characteristics of the traveling wave signals, to further refine the primary fault location candidate estimation. This comprehensive approach enables the processing arrangement to deliver reliable and accurate primary fault location candidate information, which is crucial for the effective management and maintenance of the electric grid. For instance, this information is vital for utility companies to swiftly identify, assess, and address issues within the electric grid, ultimately ensuring its reliable and efficient operation.

Optionally, the processing arrangement is further configured to:
calculate direct distances from each traveling wave fault recording unit of at least one pair of the plurality of traveling wave fault recording units to the primary fault location candidate in the faulty feeder line, based on time differences between the recorded arrival times of the detected traveling waves for each traveling wave fault recording unit of the at least one pair of the plurality of traveling wave fault recording units; and
identify the primary fault location candidate in the faulty feeder line based on the calculated direct distances.

Herein, the processing arrangement is configured to carry out a series of calculations to determine the primary fault location candidate in the electric grid by implementing arithmetic techniques. Firstly, using the recorded arrival times of the detected traveling waves from at least one pair of the two or more traveling wave fault recording units, the processing arrangement calculates the time differences between the arrival times for each unit of the pair. With these time differences, the processing arrangement computes the direct distances from each traveling wave fault recording unit of the pair to the location of the fault. These distances may be derived based on the known speed of traveling waves and the time differences between the recorded arrival times for each traveling wave fault recording unit of the pair. Herein, the term “direct distance” refers to a distance between two points measured by calculating distance of a direct straight line between the two points. Finally, the processing arrangement determines the primary fault location candidate within the faulty feeder line in the electric grid by utilizing the calculated direct distances. This may be done using various techniques, such as triangulation or trilateration, which involve the intersection of multiple lines or circles, respectively, drawn from the location coordinates of the traveling wave fault recording units. By incorporating arithmetic techniques, the processing arrangement may systematically and precisely calculate the location of the fault within the electric grid.

For instance, assuming a fault occurs at a specific location within the electric grid, the traveling wave fault recording units A, B, C, and D, whose exact location coordinates within the electric grid are already known, where A, B, C, and D, detect and record the arrival time of the traveling wave fault signals generated by the occurrence of the fault. These traveling wave fault recording units accurately timestamp the detected traveling wave fault signals, for example, by utilizing GPS time synchronization. The recorded arrival time information is then provided to the processing arrangement, which upon receiving the timestamp and location information from the traveling wave fault recording units A, B, C, and D, determines the fault location by applying arithmetic techniques. The processing arrangement calculates the direct distances between the fault location and each of the recording units based on the differences in the recorded arrival times. By combining this distance information with the known dimensions of the electric grid and the location coordinates of the traveling wave fault recording units, the processing arrangement is able to accurately resolve the fault location within the electric grid.

The processing arrangement is further configured to:
calculate line distances from each traveling wave fault recording unit of multiple pairs of the plurality of traveling wave fault recording units to the primary fault location candidate in the faulty feeder line, based on time differences between the recorded arrival times of the detected traveling waves for each traveling wave fault recording unit of the multiple pairs of the plurality of traveling wave fault recording units; and
identify the primary fault location candidate in the faulty feeder line based on the calculated line distances.

Herein, the processing arrangement is configured to perform a series of steps that utilize a more intuitive approach to determining the primary fault location candidate within the electric grid by implementing heuristic techniques. Herein, the processing arrangement calculates the time differences between the recorded arrival times of the detected traveling waves for each traveling wave fault recording unit of multiple pairs of the plurality of traveling wave fault recording units. Using these time differences, the processing arrangement computes the line distances from each traveling wave fault recording unit of the multiple pairs to the location of the fault. These line distances may be calculated considering the known speed of traveling waves and the time differences between the recorded arrival times for each recording unit of the multiple pairs. Herein, the term “line distance” refers to a distance between two points measured by calculating a length of the feeder line that runs between the two points. The processing arrangement then determines the location of the fault within an electric grid by analysing the calculated line distances and known dimensions of the electric grid. This may be achieved using heuristic methods that consider various combinations of line distances and electric grid dimensions to generate a set of potential fault locations. The processing arrangement may then select the most plausible fault location from this set based on additional criteria, such as the consistency of the results or the presence of physical barriers in the grid. By employing heuristic techniques, the processing arrangement may effectively estimate the primary fault location candidate within the electric grid using a more flexible and adaptable approach. This methodology is particularly useful in scenarios where the grid's complexity or incomplete information may hinder the application of more rigid arithmetic techniques. The heuristic approach allows the processing arrangement to incorporate multiple factors and weigh them against each other to generate a reliable primary fault location candidate estimate, ultimately helping utility companies to address issues in the electric grid more efficiently and effectively.

For instance, in an exemplary 6 km×6 km electric grid, and with the traveling wave fault recording units A, B, C and D being positioned at four corners of the said electric grid with ‘A’ at (0, 0), ‘B’ at (6, 0), ‘C’ at (6, 6) and ‘D’ at (0, 6), for a fault occurring in the faulty feeder line in the grid, the traveling wave is calculated to traverse 6.5 km to reach the traveling wave fault recording unit ‘B’ and 3.5 km to reach the traveling wave fault recording unit ‘A’. The time difference corresponds to a 3 km distance, leading to a solution where the primary fault location candidate is 4.5 km from the traveling wave fault recording unit ‘B’ and 1.5 km from the traveling wave fault recording unit ‘A’.

In some examples, the processing arrangement may use a combination of arithmetic and heuristic techniques to improve the accuracy and reliability of the primary fault location candidate process. For example, it might first apply arithmetic techniques to generate an initial estimate of the primary fault location candidate, and then use heuristic techniques to refine the estimate based on additional information or contextual factors. This combined approach enables the processing arrangement to leverage the strengths of both techniques, resulting in a more accurate and robust primary fault location candidate determination.

In an embodiment, the processing arrangement is configured to identify the primary fault location candidate based on the received information of the plurality of traveling wave fault recording units, using at least one of: a machine learning model, an artificial intelligence model, a mathematical model, and the like. Herein, both the machine learning model and the artificial intelligence model are trained to identify the primary fault location candidate based on the received information of the plurality of traveling wave fault recording units using previously stored data of fault locations identified based on the previously stored data of the plurality of travelling wave fault recording units for those faults which have previously occurred.

Furthermore, the processing arrangement is configured to receive, from the one or more sensor units, installed in the faulty feeder line, the one or more measured current values during the occurrence of the fault, wherein the given measured current value corresponds to the fault current value in the faulty feeder line when the given measured current value represents the phase-to-phase, phase-to-neutral, or phase-to-ground fault. Throughout the present disclosure, the term “sensor unit” refers to a device having sensing capabilities to sense and collect data for measuring the one or more current values. Optionally, the one or more sensor units are one of: protection relays, fault passage indicators, current measurement devices, and the like. Notably, each feeder line present in the electric grid has corresponding one or more sensor units installed therein. Although, the processing arrangement receives the measured one or more current values only from the one or more sensor units installed in the faulty feeder line. Subsequently, the processing arrangement is communicably coupled with the one or more sensor units installed in the faulty feeder line to receive the measured one or more current values. Optionally, the processing arrangement is communicably with one or more sensor units installed in the faulty feeder line via a wireless communication interface (for example a Wi-Fi® module, a GSM module, and the like).

Throughout the present disclosure, the term “fault current value” refers to a value of fault current that flows through the faulty feeder line during the occurrence of the fault. Notably, the fault current is generated in the faulty feeder line when unintended paths for flow of current are created in the faulty feeder line due to the occurrence of the fault. Herein, the phase-to-phase fault and the low impedance phase-to-neutral, or phase-to-ground fault are two different types of fault that may occur in the given feeder line of the electric grid. It will be appreciated that the occurrence of either the phase-to-phase, phase-to-neutral, or phase-to-ground fault results in the flow of the fault current in the faulty feeder line. Subsequently, when the given measured current value indicates the occurrence of either the low impedance phase-to-phase, phase-to-neutral, or phase-to-ground fault in the faulty feeder line, the given measured current value corresponds to being the fault current value. Notably, the given measured current value corresponds to the fault current value only in case of a direct fault in the faulty feeder line, i.e., when a fault impedance is measured to be lower than a grid and a transformer impedance.

Furthermore, the processing arrangement is configured to identify the one or many secondary fault location candidates in the faulty feeder line, based on the processing of the received fault current value for each corresponding branch from amongst the plurality of branches of the faulty feeder line. Notably, each feeder line in the electric grid comprises the plurality of branches arising from thereof. Subsequently, the fault current value for each corresponding branch from amongst the plurality of branches of the faulty feeder line is to be received to accurately determine the one or many secondary fault location candidates. In an embodiment, the processing arrangement receives the same fault current value for each corresponding branch from amongst the plurality of branches in the faulty feeder line. In another embodiment, the processing arrangement receives multiple fault current values for the plurality of branches of the faulty feeder line. Throughout the present disclosure, the term “secondary fault location candidate” refers to that possible location of fault which is determined by processing of the received fault current values. It will be appreciated that the received one or more fault current values are indicative of the one or many secondary fault location candidates, where that indication is analyzed and determined from the processing of the received fault current values.

Optionally, the processing arrangement is further configured to:
receive, measured before the occurrence of the fault to be located, information corresponding to:
   a plurality of fault current values, from the one or more sensor units, and
   a plurality of associated fault locations for the plurality of branches of the given feeder line; and
identify the one or many secondary fault location candidates for the received one or more fault current values, during the occurrence of the fault, using interpolation, extrapolation or heuristic techniques on the information corresponding to the received plurality of fault current values and the plurality of associated fault locations.

In this regard, the system creates a mapping of where a given fault location is possibly located for a given fault current value. Notably, the plurality of fault current values comprises of different fault current values that are received from the one or more sensor units in the given feeder line for the previously occurred faults (i.e., those faults which have occurred before the occurrence of the fault that is to be detected in the system). Subsequently, the plurality of associated fault locations comprises of a given fault location detected for each of the corresponding fault current value. Notably, the plurality of associated fault locations are received from previously stored database that is collected by on-site human validation of the location of the fault. It will be appreciated that different techniques such as the interpolation, extrapolation or heuristics techniques involve use of various mathematical functions to beneficially, analyze and recognize patterns and relationships between the plurality of fault current values and the plurality of associated fault locations. Subsequently, the analyzed and recognized patterns between the plurality of fault current values and the plurality of associated fault locations advantageously, enables to identify the one or many secondary fault location candidates based on the received one or more fault current values, during the occurrence of the fault. It will be appreciated that herein the processing of the received one or more fault current values relates to using interpolation, extrapolation or heuristic techniques on the received one or more fault current values, during the occurrence of the fault.

Optionally, the processing arrangement is further configured to:
receive, before the occurrence of the fault to be located, the information corresponding to:
   the plurality of fault current values, from the one or more sensor units, and
   the plurality of associated fault locations for the plurality of fault current values in the given feeder line;
create a training dataset based on the plurality of fault current values and the plurality of associated fault locations, wherein the training dataset is indicative of the one or many secondary fault location candidates, during the occurrence of the fault; and
train a machine learning model to identify the one or many secondary fault location candidates for the received one or more fault current values, using the training dataset, during the occurrence of the fault, or using mathematical calculations on the training dataset to interpolate or extrapolate the fault location candidate during the occurrence of the fault.

In this regard, the term “training dataset” refers to a dataset that is indicative what the given fault location is for corresponding fault current value in the given feeder line based on the plurality of associated fault locations for the plurality of fault current values in the given feeder line. Notably, the training dataset is created to be used to train the machine learning model that can effectively identify a said fault location for a said one or more fault current values in the given feeder line. Herein, the processing arrangement is configured to train the machine learning model to analyze and learn different recognizable patterns and relationships between the plurality of the fault current values and the plurality of the associated fault locations in the given feeder line. Subsequently, based on the training of the machine learning model, the machine learning model identifies the one or many secondary fault location candidates based on the received one or more fault current values. It will be appreciated that herein the processing of the received one or more fault current values relates to implementing the machine learning model on the received one or more fault current values, during the occurrence of the fault to identify the one or many secondary fault location candidates. Thus, advantageously, the system is able to effectively implement self-learning via the use of the machine learning model to produce more accurate results in determining the one or many secondary fault location candidates.

Optionally, the processing arrangement is further configured to receive from the one or more sensor units, directions of a power flow of the plurality of fault current values measured. Throughout the present disclosure, the term “direction of power flow” refers to a direction in which the power is being transmitted due to the flow of the fault current. The technical effect of receiving the directions of the power flow of the plurality of fault current values measured is that the direction of the power flow for the given fault current value is beneficially used to validate an accuracy of the given secondary fault location candidate that is identified by processing of the given fault current value.

Furthermore, the processing arrangement is configured to determine the fault location based on the comparison of the identified primary fault location candidate and the one or many secondary fault location candidates in the faulty feeder line. Herein, the comparison of the identified primary fault location and the one or many secondary fault location relates to integrating information about the identified primary fault location candidate with information about the one or many secondary fault location candidates to determine the fault location. In an embodiment, the comparison of the identified primary fault location candidate and the one or many secondary fault location candidate relates to determining a location where the identified primary fault location candidate and one of the one or many secondary fault location candidates coincides. Subsequently, the location of coincidence is determined as the fault location. In another embodiment, the comparison of the identified primary fault location candidate and the one or many secondary fault location candidates relates to determining a location obtained by adjusting the identified primary fault location candidate based on the one or many secondary fault location candidates. Subsequently, the location determined by adjusting the primary fault location candidate based on the one or many secondary fault location candidates is determined as the fault location.

Optionally, the processing arrangement is further configured to:
receive, from the one or more sensor units, the plurality of fault current values in the faulty feeder line, wherein the faulty feeder line is connected to a plurality of power sources and each fault current value from amongst the plurality of fault current values is generated by a corresponding power source from amongst the plurality of power sources connected to the faulty feeder line;
identify a plurality of secondary fault location candidates in the faulty feeder line, based on the processing of the received plurality of fault current values; and
determine the fault location based on the comparison of the identified primary fault location candidate and the plurality of secondary fault location candidates in the faulty feeder line.

In this regard, the term “plurality of power sources” refers to a multiple sources of electricity connected to the faulty feeder line which supply current to the faulty feeder line. Notably, from each power source connected to the faulty feeder line, a corresponding fault current flows in the faulty feeder line. Subsequently, the plurality of fault current values are received for the plurality of the power sources connected to the faulty feeder line. It will be appreciated that the plurality of secondary fault location candidates are identified as a result of the processing of the plurality of fault current values in the faulty feeder line. Optionally, the plurality of secondary fault location candidates comprises multiple secondary fault location candidates identified for each fault current value from amongst the plurality of fault current values in the faulty feeder line. Subsequently, the identified primary fault location candidate is compared with the plurality of the secondary fault location candidates to determine the fault location. Thus, beneficially, the system is able to efficiently and accurately determine the fault location in a scenario, where the faulty feeder line is connected to the plurality of power sources.

Optionally, the primary fault location candidate is located at a root of one or more branches in the faulty feeder line, or near a root of one or more branches in the faulty feeder line, and the one or more secondary fault location candidates are located in a faulty branch from amongst the one or more branches, wherein the processing arrangement is configured to determine the fault location in the faulty branch in the faulty feeder line based on the comparison of the identified primary fault location candidate and the one or many secondary fault location candidates. Herein, the term “root of one or more branches” refers to a point from where one or more branches originate from the faulty feeder line. Notably, the information received from the plurality of the traveling wave fault recording units can be only used to accurately identify the primary fault location up to the root of the one or more branches in the faulty feeder line. Thus, if the fault location is at the faulty branch (i.e., a given branch from amongst the one or more branches in which the fault has occurred) of the faulty feeder line, then it remains undetected in the primary fault location candidate. Although, the one or many secondary fault location candidates are identified in the faulty branch. Thus, advantageously, the comparison of the identified primary fault location candidate and the one or many secondary fault location candidates is able to accurate determine the fault location in the faulty branch in the faulty feeder line.

The present disclosure also relates to the method as described above. Various embodiments and variants disclosed above, with respect to the aforementioned system, apply mutatis mutandis to the method.

Optionally, the method further comprises detecting the traveling waves which traverse along the one or more of: neutral wire(s), ground wire(s), cable shield(s) thus propagating over open switches or gaps in the feeder lines in the electric grid.

Optionally, the method further comprises:
calculating direct distances from each traveling wave fault recording unit of at least one pair of the plurality of traveling wave fault recording units to the primary fault location candidate in the faulty feeder line, based on time differences between the recorded arrival times of the detected traveling waves for each traveling wave fault recording unit of the at least one pair of the plurality of traveling wave fault recording units; and
identifying the primary fault location candidate in the faulty feeder line based on the calculated direct distances.

Optionally, the method further comprises:
calculating line distances from each traveling wave fault recording unit of multiple pairs of the plurality of traveling wave fault recording units to the primary fault location candidate in the faulty feeder line, based on time differences between the recorded arrival times of the detected traveling waves for each traveling wave fault recording unit of the multiple pairs of the plurality of traveling wave fault recording units; and
identifying the primary fault location candidate in the faulty feeder line based on the calculated line distances.

Optionally, the method further comprises:
receiving, before the occurrence of the fault to be located, information corresponding to:
   a plurality of fault current values, from the one or more sensor units, and
   a plurality of associated fault locations for the plurality of fault current values in the given feeder line;
creating a training dataset based on the plurality of fault current values and the plurality of associated fault locations, wherein the training dataset is indicative of the one or many secondary fault location candidates, during the occurrence of the fault; and
train a machine learning model to identify the one or many secondary fault location candidates for the received one or more fault current values, using the training dataset, during the occurrence of the fault, or using mathematical calculations on the training dataset to interpolate or extrapolate the fault location candidate during the occurrence of the fault.

Optionally, the method further comprises receiving, from the one or more sensor units, via the processing arrangement, directions of a power flow of the fault current values measured.

### DETAILED DESCRIPTION OF THE DRAWINGS

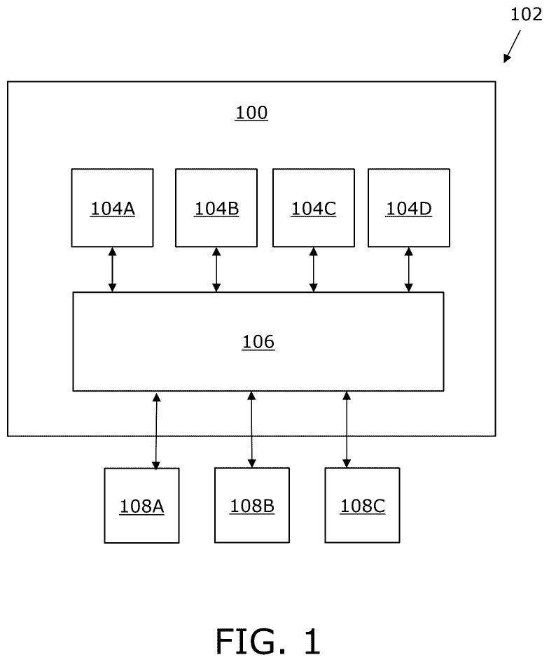

Referring to FIG. 1, illustrated is a block diagram of a system 100 for detection of a fault location in an electric grid 102, in accordance with an embodiment of the present disclosure. As shown in FIG. 1, the system 100 comprises a plurality of traveling wave fault recording units (depicted as traveling wave fault recording units 104A, 104B, 104C, and 104D) configured to be installed at various locations on the feeder line in the electric grid 102. Moreover, the system 100 comprises a processing arrangement 106, wherein the processing arrangement 106 is communicably coupled with the plurality of traveling wave fault recording units 104A, 104B, 104B, 104D. Furthermore, the processing arrangement 106 is configured to receive one or more measured current values from one or more sensor units (depicted as sensor units 108A, 108B and 108C) installed in a faulty feeder line of the electric grid 102. Furthermore, any of the sensor unit capable of measuring line current values can be incorporated into a unit acting also as a traveling wave fault recorder unit.

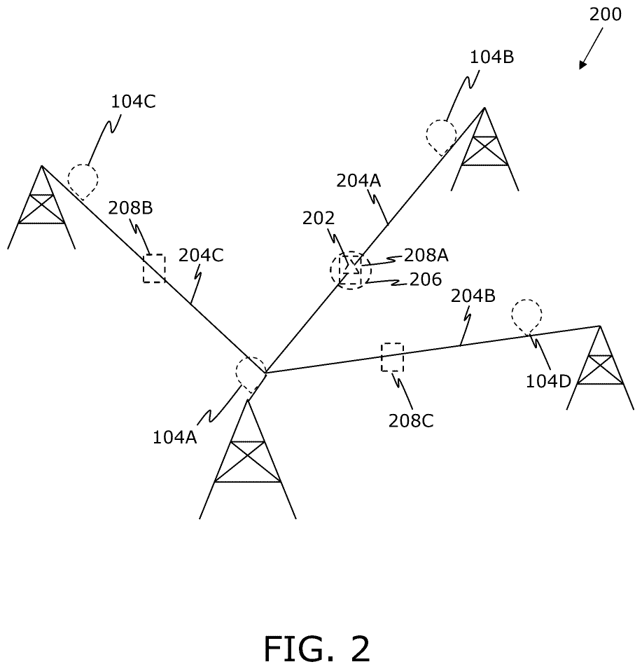

Referring to FIG. 2, illustrated is a schematic illustration of an electric grid 200 depicting a detection of a fault location 202, in accordance with an embodiment of the present disclosure. As shown in FIG. 2, a plurality of feeder lines (depicted as feeder lines 204A, 204B and 204C) are present in the electric grid 200. Herein, a primary fault location candidate 206 is identified in the electric grid 200 using the plurality of travelling wave fault recording units 104A, 104B, 104C, 104D. Subsequently, the identification of the primary fault location candidate 206 leads to the feeder line 204A to be identified as a faulty feeder line. Moreover, one or many secondary fault location candidates 208A, 208B, and 208C are identified in the faulty feeder line 204A. Furthermore, the fault location 202 is determined in the electric grid 200 based on comparison of the primary fault location candidate 206 and the one or many secondary fault location candidates 208A, 208B, 208C. Subsequently, the primary fault location candidate 206 coincides with the one or many secondary fault location candidate 208A and the fault location 202 is located in the electric grid 200.

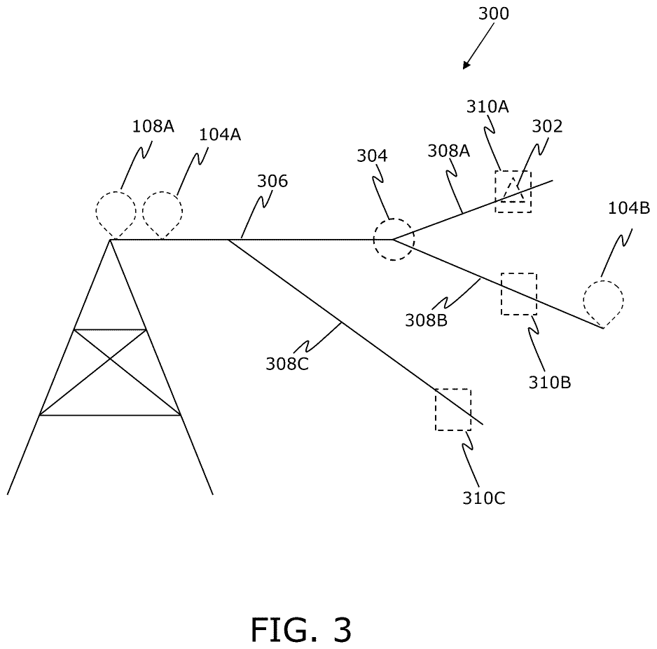

Referring to FIG. 3, illustrated is a schematic illustration of an electric grid 300 depicting a detection of a fault location 302, in accordance with an embodiment of the present disclosure. As shown in FIG. 3, a primary fault location candidate 304 is identified in a faulty feeder line 306 at a root of one or more branches (depicted as branches 308A, 308B, 308C), as a dual-ended traveling wave fault positioning based on fault signal arrival times can only detect faults strictly between traveling wave fault recording units. Moreover, the one or many secondary fault location candidates 310A, 310B, and 310C are identified in a faulty feeder branch 308A in the faulty feeder line 306. Furthermore, the fault location 302 is determined in the electric grid 300 based on comparison of the primary fault location candidate 304 and the one or many secondary fault location candidates 310A, 310B, 310C where the fault location 302 is detected in the faulty branch 308A in the faulty feeder line 306. Herein, the primary fault location candidate 304 points to the root of the faulty branch 308A in which the secondary fault location candidate 310A is identified, and thus, the other secondary fault location candidates 310B and 310C do not match the primary fault location candidate 304. Subsequently, the fault location 302 is determined at the secondary fault location candidate 310A.

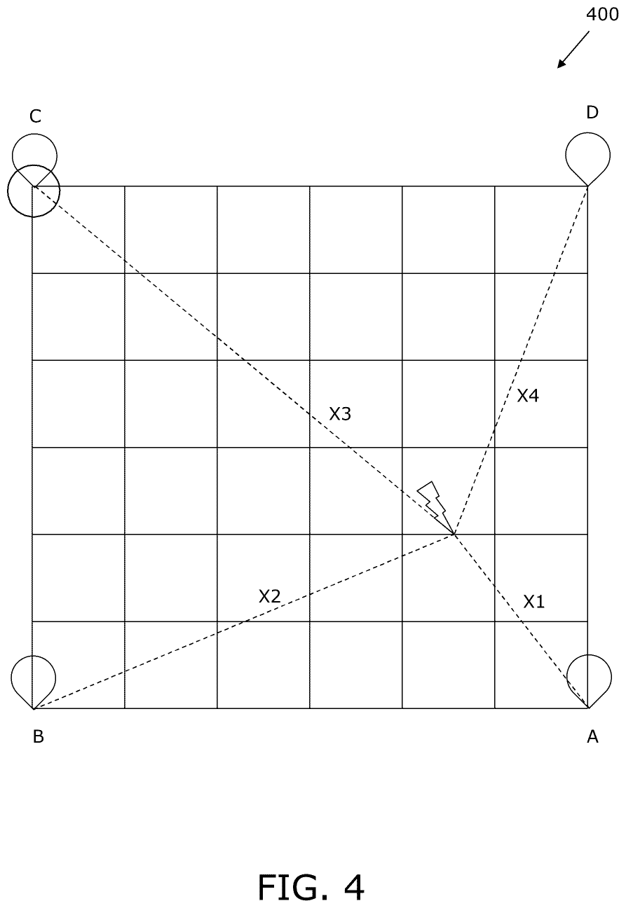

Referring to FIG. 4, illustrated is an exemplary depiction of an electric grid 400, in accordance with one or more embodiments of the present disclosure. Herein, the electric grid 400 has a substation (represented as a circle) at a top-left corner thereof. The electric grid 400 also has a plurality of traveling wave fault recording units shown as A, B, C and D, disposed at four corners thereof. By using arithmetic techniques, a processing arrangement is configured to calculate direct distances ‘X1-X4’ from each traveling wave fault recording unit ‘A-D’ within at least one pair of units to a primary fault location candidate (as represented by a lightning bolt). This calculation is based on the time differences between the recorded arrival times of detected traveling waves for each unit within the pair. Once these direct distances ‘X1-X4’ are calculated, the processing arrangement may determine the primary fault location candidate by considering both the calculated direct distances ‘X1-X4’ and the known dimensions of the electric grid 400.

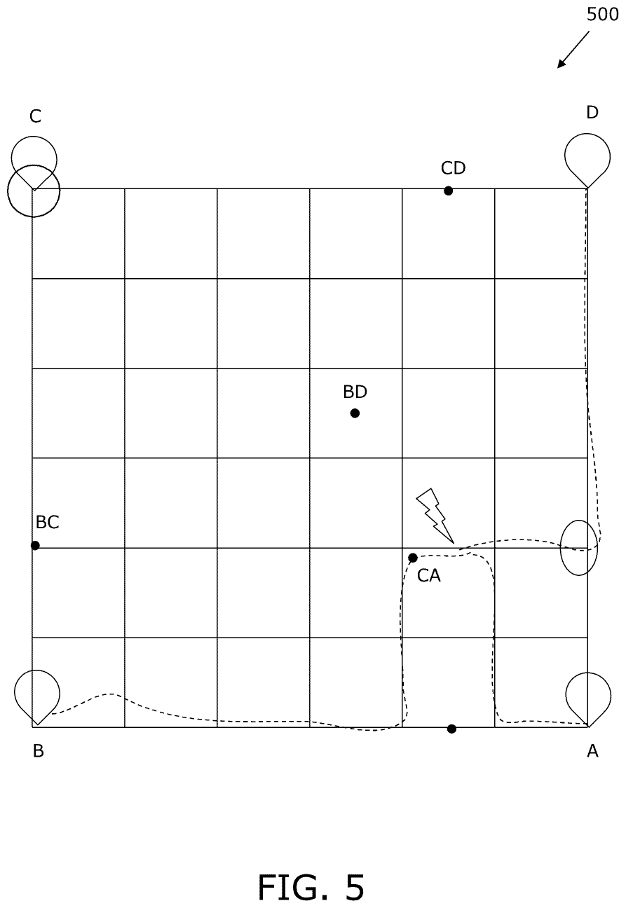

Referring to FIG. 5, illustrated is an exemplary depiction of an electric grid 500, in accordance with one or more embodiments of the present disclosure. Herein, the electric grid 500 has a substation (represented as a circle) at a top-left corner thereof. The electric grid 500 also has two or more traveling wave fault recording units shown as A, B, C and D, disposed at four corners thereof. By using heuristic techniques, a processing arrangement is configured to calculate line distances from each traveling wave fault recording unit ‘A-D’ to a primary fault location candidate (as represented by a lightning bolt). This is based on the time differences between the recorded arrival times of detected traveling waves for each unit in the multiple pairs (A-D). For instance, with a 3 length unit time difference between signals received by units ‘A’ and ‘B’, the primary fault location candidate is determined as 4.5 length units from ‘B’ and 1.5 length units from ‘A’. Similarly, other device pairs along the edges are processed. Using diagonal device pairs, such as ‘BD’, ‘BC’, ‘CA’ and ‘CD’, the processing arrangement calculates the primary fault location candidate based on the difference in the diagonal distances. This process generates multiple hints for primary fault location candidate, which may then be found mathematically, such as through triangulation, resulting in an accurate primary fault location candidate determination.

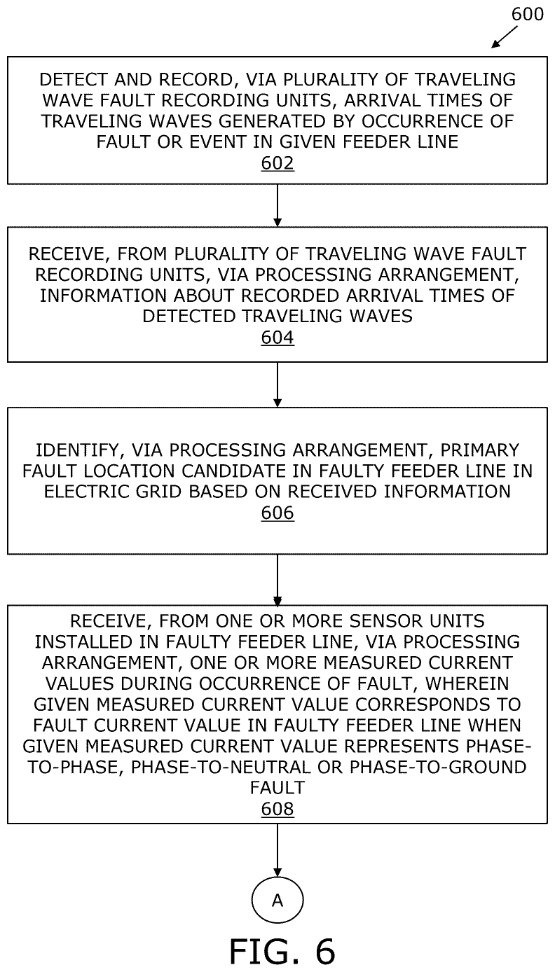

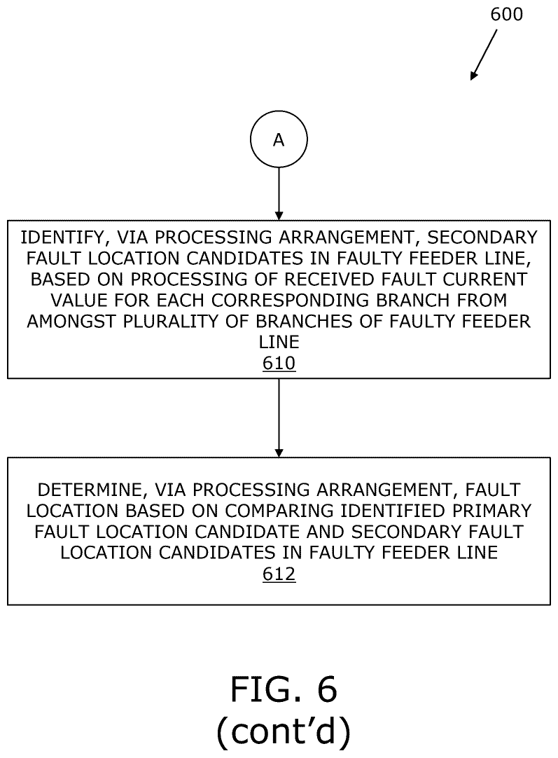

Referring to FIGS. 6 and 6 (cont'd), illustrated is a flowchart depicting steps of a method 600 for detection of a fault location in an electric grid, in accordance with an embodiment of the present disclosure. At step 602, arrival times of traveling waves generated by occurrence of a fault or an event in a given feeder line, are detected and recorded, via a plurality of traveling wave fault recording units. At step 604, information about the recorded arrival times of the detected traveling waves, are received, from the plurality of traveling wave fault recording units, via a processing arrangement. At step 606, a primary fault location candidate in a faulty feeder line in the electric grid based on the received information, are identified, via the processing arrangement. At step 608, one or more measured current values during the occurrence of the fault, are received, from one or more sensor units installed in the faulty feeder line wherein a given measured current value corresponds to a fault current value in the faulty feeder line when the given measured current value represents a phase-to-phase, phase-to-neutral, or phase-to-ground fault. At step 610, one or more secondary fault location candidates in the faulty feeder line, are identified, via the processing arrangement, based on a processing of the received fault current value for each corresponding branch from amongst a plurality of branches of the faulty feeder line. At step 612, the fault location is determined, via the processing arrangement, based on comparing the identified primary fault location candidate and the one or more secondary fault location candidates in the faulty feeder line.

1. A system for detection of a fault location in an electric grid, the system comprising:
a plurality of traveling wave fault recording units configured to be installed at locations in the electric grid, to detect and record arrival times of traveling waves generated by occurrence of a fault or an event in a given feeder line, and
a processing arrangement communicably coupled with the plurality of traveling wave fault recording units, wherein the processing arrangement is configured to:
receive, from the plurality of traveling wave fault recording units, information about the recorded arrival times of the detected traveling waves and the location coordinates thereof in the electric grid,
identify a primary fault location candidate in a faulty feeder line in the electric grid based on the received information,
receive, from one or more sensor units, installed in the faulty feeder line, one or more measured current values during the occurrence of the fault, wherein a given measured current value corresponds to a fault current value in the faulty feeder line when the given measured current value represents a phase-to-phase, phase-to-neutral, or phase-to-ground fault,
identify one or many secondary fault location candidates in the faulty feeder line, based on a processing of the received fault current value for each corresponding branch from amongst a plurality of branches of the faulty feeder line,
determine the fault location based on a comparison of the identified primary fault location candidate and the one or many secondary fault location candidates in the faulty feeder line, and
wherein the processing arrangement is further configured to:
calculate line distances from each traveling wave fault recording unit of multiple pairs of the plurality of traveling wave fault recording units to the primary fault location candidate in the faulty feeder line, based on time differences between the recorded arrival times of the detected traveling waves for each traveling wave fault recording unit of the multiple pairs of the plurality of traveling wave fault recording units; and
identify the primary fault location candidate in the faulty feeder line based on the calculated line distances.

2. The system according to claim 1, wherein the plurality of traveling wave fault recording units are configured to detect the traveling waves which traverse along one or more of: neutral wire(s), ground wire(s), cable shield(s) thus propagating over open switches or gaps in the feeder lines in the electric grid.

3. The system according to claim 1, wherein the processing arrangement is further configured to:
calculate direct distances from each traveling wave fault recording unit of at least one pair of the plurality of traveling wave fault recording units to the primary fault location candidate in the faulty feeder line, based on time differences between the recorded arrival times of the detected traveling waves for each traveling wave fault recording unit of the at least one pair of the plurality of traveling wave fault recording units; and
identify the primary fault location candidate in the faulty feeder line based on the calculated direct distances.

4. The system according to claim 1, wherein the processing arrangement is further configured to:
receive, before the occurrence of the fault to be located, information corresponding to:
a plurality of fault current values, from the one or more sensor units (108A-C), and
a plurality of associated fault locations for the plurality of fault current values in the given feeder line; and
identify the one or more secondary fault location candidates (208A-C) for the received one or more fault current values, during the occurrence of the fault, using interpolation, extrapolation or heuristic techniques on the information corresponding to the received plurality of fault current values and the plurality of associated fault locations.

5. The system according to claim 4, wherein the processing arrangement is further configured to:
receive, before the occurrence of the fault to be located, the information corresponding to:
the plurality of fault current values, from the one or more sensor units (108A-C), and
the plurality of associated fault locations for the plurality of fault current values in the given feeder line;
create a training dataset based on the plurality of fault current values and the plurality of associated fault locations, wherein the training dataset is indicative of the one or more secondary fault location candidates (208A-C), during the occurrence of the fault; and
train a machine learning model to identify the one or more secondary fault location candidates for the received one or more fault current values, using the training dataset, during the occurrence of the fault, or using mathematical calculations on the training dataset to interpolate or extrapolate the fault location candidate during the occurrence of the fault.

6. The system according to claim 1, wherein the processing arrangement is further configured to:
receive, from the one or more sensor units, the plurality of fault current values in the faulty feeder line wherein the faulty feeder line is connected to a plurality of power sources and each fault current value from amongst the plurality of fault current values is generated by a corresponding power source from amongst the plurality of power sources connected to the faulty feeder line;
identify a plurality of secondary fault location candidates in the faulty feeder line, based on the processing of the received plurality of fault current values; and
determine the fault location based on the comparison of the identified primary fault location candidate and the plurality of secondary fault location candidates in the faulty feeder line.

7. The system according to claim 1, wherein the processing arrangement is further configured to receive from the one or more sensor units, directions of a power flow of the plurality of fault current values measured.

8. The system according to claim 1, wherein the primary fault location candidate is located at a root of one or more branches in the faulty feeder line and the one or more secondary fault location candidates are located in a faulty branch from amongst the one or more branches, wherein the processing arrangement is configured to determine the fault location in the faulty branch in the faulty feeder line based on the comparison of the identified primary fault location candidate and the one or many secondary fault location candidates.

9. A method for detection of a fault location in an electric grid, the method comprising:
detecting and recording, via a plurality of traveling wave fault recording units, arrival times of traveling waves generated by occurrence of a fault or an event in a given feeder line;
receiving, from the plurality of traveling wave fault recording units, via a processing arrangement, information about the recorded arrival times of the detected traveling waves;
identifying, via the processing arrangement, a primary fault location candidate in a faulty feeder line in the electric grid based on the received information;
receiving, from one or more sensor units installed in the faulty feeder line, via the processing arrangement, one or more measured current values during the occurrence of the fault, wherein a given measured current value corresponds to a fault current value in the faulty feeder line when the given measured current value represents a phase-to-phase, phase-to-neutral, or phase-to-ground fault;
identifying, via the processing arrangement, one or more secondary fault location candidates in the faulty feeder line, based on a processing of the received fault current value for each corresponding branch from amongst a plurality of branches of the faulty feeder line; and
determining, via the processing arrangement, the fault location based on comparing the identified primary fault location candidate and the one or more secondary fault location candidates in the faulty feeder line, and
wherein the method further comprises:
calculating line distances from each traveling wave fault recording unit of multiple pairs of the plurality of traveling wave fault recording units to the primary fault location candidate in the faulty feeder line, based on time differences between the recorded arrival times of the detected traveling waves for each traveling wave fault recording unit of the multiple pairs of the plurality of traveling wave fault recording units; and
identifying the primary fault location candidate in the faulty feeder line based on the calculated line distances.

10. The method according to claim 9, wherein the method further comprises detecting the traveling waves which traverse along the one or more of: neutral wire(s), ground wire(s), cable shield(s) thus propagating over open switches or gaps in the feeder lines in the electric grid.

11. The method according to claim 9, wherein the method further comprises:
calculating direct distances from each traveling wave fault recording unit of at least one pair of the plurality of traveling wave fault recording units to the primary fault location candidate in the faulty feeder line, based on time differences between the recorded arrival times of the detected traveling waves for each traveling wave fault recording unit of the at least one pair of the plurality of traveling wave fault recording units; and
identifying the primary fault location in the faulty feeder line based on the calculated direct distances.

12. The method according to claim 9, wherein the method further comprises:
receiving, before the occurrence of the fault to be located, information corresponding to:
a plurality of fault current values, from the one or more sensor units, and
a plurality of associated fault locations for the plurality of fault current values in the given feeder line;
creating a training dataset based on the plurality of fault current values and the plurality of associated fault locations, wherein the training dataset is indicative of the one or more secondary fault location candidates (208A-C), during the occurrence of the fault; and
train a machine learning model to identify the one or more secondary fault location candidates for the received one or more fault current values, using the training dataset, during the occurrence of the fault, or using mathematical calculations on the training dataset to interpolate or extrapolate the fault location candidate during the occurrence of the fault.

13. The method according to claim 9, wherein the method further comprises receiving, from the one or more sensor units, via the processing arrangement, directions of a power flow of the fault current values measured.
